(19) United States
(12) Patent Application Publication
(10) Pub. No.: US 2022/0301975 A1
(43) Pub. Date: Sep. 22, 2022

(54) ELECTRONIC COMPONENT-EMBEDDED SUBSTRATE

(71) Applicant: SAMSUNG ELECTRO-MECHANICS CO., LTD., Suwon-si (KR)

(72) Inventors: Ho Hyung HAM, Suwon-si (KR); Gun Hwi HYUNG, Suwon-si (KR); Jun Hyeong JANG, Suwon-si (KR); Tae Hong MIN, Suwon-si (KR)

(21) Appl. No.: 17/339,451

(22) Filed: Jun. 4, 2021

(30) Foreign Application Priority Data
Mar. 19, 2021 (KR) 10-2021-0035765

(51) Int. Cl. H01L 23/373; H05K 1/02; H05K 1/18; H05K 1/03; H01L 23/367; H01L 23/13; H01L 23/498; H01L 21/48

(52) U.S. Cl. CPC H01L 23/3737; H05K 1/0206; H05K 1/186; H05K 1/036; H01L 23/367; H01L 23/13; H01L 23/49827; H01L 21/481; H01L 21/486; H05K 2201/0281; H01L 24/73

(57) ABSTRACT

An electronic component-embedded substrate includes a core layer, a first cavity formed in the core layer, a heat dissipating member disposed in the first cavity and having a second cavity, and an electronic component disposed in the second cavity. The heat dissipating member includes a carbon fiber reinforced polymer (CFRP).

### CROSS-REFERENCE TO RELATED APPLICATION(S)

This application claims benefit under 35 USC 119(a) of Korean Patent Application No. 10-2021-0035765 filed on Mar. 19, 2021 in the Korean Intellectual Property Office, the entire disclosure of which is incorporated herein by reference for all purposes.

### TECHNICAL FIELD

The present disclosure relates to an electronic component-embedded substrate, and more particularly, to an electronic component-embedded substrate in which a heat dissipating member is embedded.

### BACKGROUND

When a chip is embedded by mounting the chip in a cavity of an electronic component-embedded substrate, it may be advantageous that the thickness of a substrate be reduced. However, in the case of the substrate in which a chip is embedded, heat dissipation properties of an insulating material surrounding the interior of the chip may be relatively low, and thus, heat generated by the chip is not effectively discharged. Therefore, it is necessary to develop a heat dissipation structure in which heat generated from the embedded chip may be effectively discharged.

In detail, in the case of a module-type package electronic component-embedded substrate in which a plurality of chips are embedded, generated heat is further increased, and the task of solving the heat generated inside of the substrate is urgent.

### SUMMARY

This summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

An aspect of the present disclosure is to provide an electronic component-embedded substrate in which an electronic component is embedded in a cavity, to be thinner.

An aspect of the present disclosure is to provide an electronic component-embedded substrate having improved heat dissipation characteristics by including a heat dissipating member in a cavity.

An aspect of the present disclosure is to provide an electronic component-embedded substrate having improved heat dissipation characteristics by embedding an electronic component in a cavity in a heat dissipating member.

An aspect of the present disclosure is to provide an electronic component-embedded substrate in which warpage may be controlled by utilizing a heat dissipating member having a low coefficient of thermal expansion (CTE).

According to an aspect of the present disclosure, there is provided an electronic component-embedded substrate advantageous for thinning and heat dissipation of a substrate, in which a heat dissipating member is embedded in a cavity in a core layer without a separate adhesive and an electronic component is disposed in another cavity formed in the heat dissipating member.

According to an aspect of the present disclosure, an electronic component-embedded substrate includes a core layer, a first cavity formed in the core layer, a heat dissipating member disposed in the first cavity and having a second cavity, and an electronic component disposed in the second cavity. The heat dissipating member includes a carbon fiber reinforced polymer (CFRP).

According to an aspect of the present disclosure, an electronic component-embedded substrate includes a core layer, a plurality of first cavities disposed in the core layer, a first wiring layer disposed on one surface of the core layer, an electronic component embedded in at least a portion of the plurality of first cavities, and a heat dissipating member embedded in at least a portion of the plurality of first cavities.

According to an aspect of the present disclosure, an electronic component-embedded substrate includes a core layer, a first cavity disposed in the core layer; a heat dissipating member disposed in the first cavity and having a second cavity; an electronic component disposed in the second cavity; and a first heat dissipation via penetrating through the first cavity and being in contact with the heat dissipating member.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a schematic cross-sectional view illustrating an example of an electronic component-embedded substrate;

FIG. 4 is a schematic plan view of the electronic component-embedded substrate of FIG. 3, taken along line I-I′;

FIG. 5 is a schematic cross-sectional view illustrating a structure in which a passivation layer is further disposed on the electronic component-embedded substrate of FIG. 3;

FIG. 6 is a schematic cross-sectional view illustrating a structure in which a through-via is further disposed on the electronic component-embedded substrate of FIG. 5;

FIG. 7 is a schematic cross-sectional view of another example of an electronic component-embedded substrate;

FIG. 8 is a schematic cross-sectional view illustrating a structure in which a passivation layer is further disposed on the electronic component-embedded substrate of FIG. 7;

FIG. 9 is a schematic cross-sectional view illustrating a structure in which a through-via is further disposed in the electronic component-embedded substrate of FIG. 8;

FIG. 10 is a schematic cross-sectional view of another example of an electronic component-embedded substrate;

FIG. 11 is a schematic cutaway plan view of the electronic component-embedded substrate of FIG. 10, taken along line II-II′;

FIG. 12 is a schematic cross-sectional view illustrating a structure in which a passivation layer is further disposed on the electronic component-embedded substrate of FIG. 10;

FIG. 13 is a schematic cross-sectional view of another example of an electronic component-embedded substrate;

FIG. 14 is one example of a schematic plan view taken along line III-III′ of the electronic component-embedded substrate of FIG. 13;

FIG. 15 is another example of a schematic plan view taken along line III-III′ of the electronic component-embedded substrate of FIG. 13;

FIG. 16 is another example of a schematic plan view taken along line III-III′ of the electronic component-embedded substrate of FIG. 13;

FIG. 17 is a schematic cross-sectional view illustrating a structure in which a passivation layer is further disposed on the electronic component-embedded substrate of FIG. 13;

FIG. 18 is a schematic cross-sectional view illustrating a structure in which a through-via is further disposed in the electronic component-embedded substrate of FIG. 17;

FIG. 19 is a schematic cross-sectional view of another example of an electronic component-embedded substrate;

FIG. 20 is a schematic cross-sectional view illustrating a structure in which a passivation layer is further disposed on the electronic component-embedded substrate of FIG. 19;

FIG. 21 is a schematic cross-sectional view illustrating a structure in which through-vias are further disposed on the electronic component-embedded substrate of FIG. 20;

FIG. 22 is a schematic cross-sectional view of another example of an electronic component-embedded substrate;

FIG. 23 is a schematic cross-sectional view illustrating a structure in which a passivation layer is further disposed on the electronic component-embedded substrate of FIG. 22;

FIG. 24 is a schematic cross-sectional view illustrating a structure in which through-vias are further disposed in the electronic component-embedded substrate of FIG. 23; and

FIGS. 25 to 34 are cross-sectional views schematically illustrating an example of manufacturing the electronic component-embedded substrate of FIG. 13.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an embodiment or example, e.g., as to what an embodiment or example may include or implement, means that at least one embodiment or example exists in which such a feature is included or implemented while all examples and examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other manners (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various manners as will be apparent after gaining an understanding of the disclosure of this application. Further, although the examples described herein have a variety of configurations, other configurations are possible as will be apparent after gaining an understanding of the disclosure of this application.

The drawings may not be to scale, and the relative sizes, proportions, and depiction of elements in the drawings may be exaggerated for clarity, illustration, and convenience.

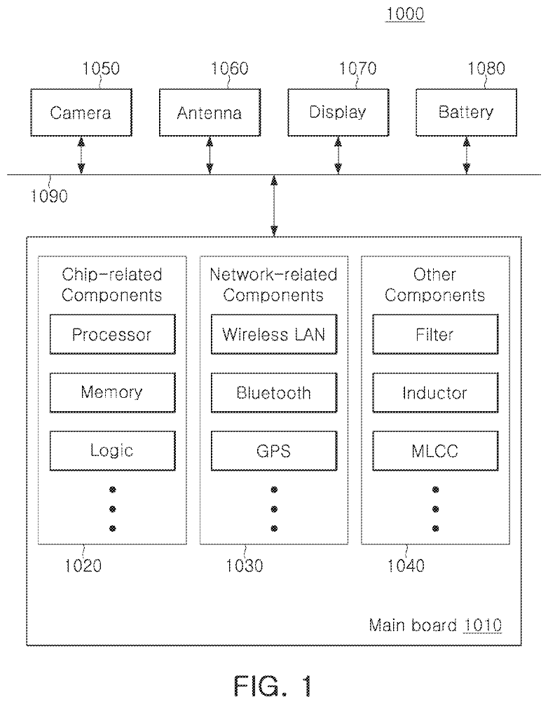

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other. The chip related components 1020 may also be in the form of a package including the above-described chip.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with the chip related components 1020, to be provided in the form of a package.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with the chip related components 1020 and/or the network related components 103, to be provided in the form of a package.

Depending on a type of the electronic device 1000, the electronic device 1000 may include other electronic components that may or may not be physically or electrically connected to the mainboard 1010. These other electronic components may include, for example, a camera module 1050, an antenna module 1060, a display 1070, a battery 1080, or the like. Other electronic components are not limited thereto, and may also include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. These other electronic components may also include other electronic components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

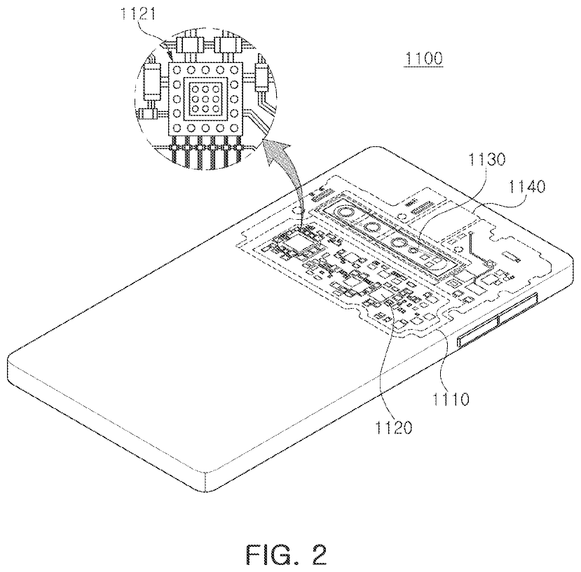

FIG. 2 is a schematic perspective view illustrating an example of an electronic device.

Referring to FIG. 2, the electronic device may be, for example, a smartphone 1100. A motherboard 1110 is accommodated in the smartphone 1100, and various electronic components 1120 may be physically or electrically connected to the motherboard 1110. In addition, a camera module 1130 and/or a speaker 1140, and the like may be accommodated in the smartphone 1100. Some of the electronic components 1120 may be the chip related components described above, for example, an electronic component-embedded substrate, but are not limited thereto. The electronic component-embedded substrate 1121 may have a form in which an electronic component is embedded in a multilayer electronic component-embedded substrate, but the configuration type is not limited thereto. On the other hand, the electronic device is not necessarily limited to the smartphone 1100, and may be other electronic devices as described above.

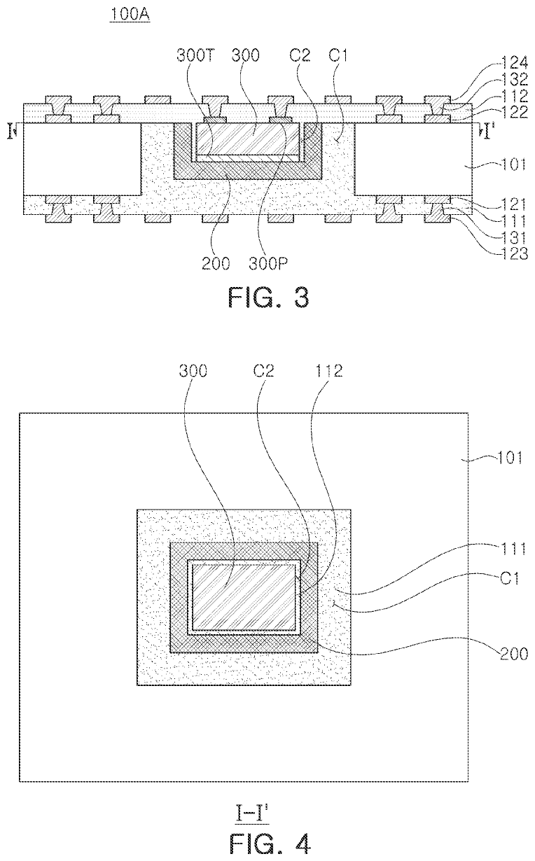

FIG. 3 is a schematic cross-sectional view illustrating an example of an electronic component-embedded substrate.

FIG. 4 is a schematic plan view of the electronic component-embedded substrate of FIG. 3, taken along line I-I′.

Referring to FIGS. 3 and 4, an electronic component-embedded substrate 100A according to a first embodiment may include a core layer 101 in which a first cavity C1 is formed, a heat dissipating member 200 disposed in the first cavity C1 and having a second cavity C2 formed therein, an electronic component 300 disposed in the second cavity C2, a first encapsulant 111 disposed on one surface of the core layer 101 to fill at least a portion of the first cavity C1 and cover at least a portion of the heat dissipating member 200, a second encapsulant 112 disposed on the other surface of the core layer 101 to fill at least a portion of the second cavity C2, and covering at least a portion of each of the heat dissipating member 200 and the electronic components 300, first and second wiring layers 121 and 122 disposed on one surface and the other surface of the core layer 101, respectively, third and fourth wiring layers 123 and 124 disposed on the first and second encapsulants 111 and 112, respectively, a first via 131 electrically connecting the first and third wiring layers 121 and 123, and a second via 132 electrically connecting the second and fourth wiring layers 122 and 124.

For example, as in the process to be described later, after processing the first cavity C1 in the core layer 101, the heat dissipating member 200 is embedded in the first cavity C1, thereby manufacturing the electronic component-embedded substrate 100A according to the first embodiment. In this case, since the heat dissipating member 200 is embedded in the first cavity C1, the substrate may be formed to be relatively thinner and smaller, and the heat dissipation characteristics of the electronic component-embedded substrate 100A may be improved. In detail, the heat dissipation characteristics in a horizontal direction may be further improved. In addition, due to the characteristics of the heat dissipating member 200 having a low coefficient of thermal expansion (CTE), warpage of the entire substrate may be controlled.

On the other hand, in the electronic component-embedded substrate 100A according to the first embodiment, the electronic component 300 may be embedded in the second cavity C2 formed in the heat dissipating member 200. Although the heat dissipating member 200 and the electronic component 300 are disposed together, the electronic component-embedded substrate 100A may have a relatively reduced thickness. In addition, heat generated by the electronic component 300 may be effectively released, and in detail, heat conduction in a horizontal direction may be further improved.

On the other hand, in the electronic component-embedded substrate 100A according to the first embodiment, the heat dissipating member 200 and the electronic component 300 may be covered by at least one of the first and second encapsulants 111 and 112. In this case, the heat dissipating member 200 and the electronic component 300 may be embedded in at least one of the first and second encapsulants 111 and 112 without a separate adhesive film and a separate metal pattern for a stopper, and the heat dissipating member 200 and the electronic component 300 may be disposed in the first cavity C1. Therefore, the electronic component-embedded substrate 100A with thickness reduction may be provided. In addition, by lowering the overall thickness, the central axis between the upper and lower portions of the substrate may be brought close to the electronic component 300, and the area ratio occupied by the electronic component 300 in the substrate may be increased, thereby reducing warpage.

On the other hand, the electronic component-embedded substrate 100A according to the first embodiment may include a plurality of wiring layers 121, 122, 123 and 124. Based on the core layer 101, first and third wiring layers 121 and 123 may be disposed on one surface side of the core layer 101, and second and fourth wiring layers 122 and 124 may be disposed on side of the other surface opposing the one surface. The first and second wiring layers 121 and 122 may be disposed on one surface and the other surface of the core layer 101, respectively, and the third and fourth wiring layers 123 and 124 may be disposed on the first and second encapsulants 111 and 112, respectively. In addition, the first and second encapsulants 111 and 112 may cover at least portions of the first and second wiring layers 121 and 122, respectively.

On the other hand, the electronic component-embedded substrate 100A according to the first embodiment may include the first via 131 electrically connecting the first and third wiring layers 121 and 123, and the second via 132 electrically connecting the second and fourth wiring layers 122 and 124. The first and second vias 131 and 132 may have tapered shapes in opposite directions. The first and second vias 131 and 132 may penetrate through at least portions of the first and second encapsulants 111 and 112, respectively. On the other hand, at least a portion of the second via 132 may penetrate through at least a portion of the second encapsulant 112 and may electrically connect the fourth wiring layer 124 and the electronic component 300. In this case, among the second vias 132, the heights and/or diameters of the second via 132 connected to the second wiring layer 122 and the second via 132 connected to the electronic component 300 may be different.

On the other hand, in the electronic component-embedded substrate 100A according to the first embodiment, as a result of a process to be described later, the other surface of the core layer 101 and the other surfaces of the first encapsulant 111 and the heat dissipating member 200 may be coplanar with each other. In addition, the second encapsulant 112 may cover the respective other surfaces of the core layer 101, the first encapsulant 111 and the heat dissipating member 200 and may fill the second cavity C2.

Hereinafter, components of the electronic component-embedded substrate 100A according to the first embodiment will be described in more detail with reference to the drawings.

The core layer 101 may further improve the rigidity of the electronic component-embedded substrate 100A according to a detailed material, and may serve to secure the uniformity of the thickness of the first and second encapsulants 111 and 112. The core layer 101 has the first cavity C1 penetrating therethrough. The first cavity C1 may be a closed space in which all four sides are blocked, but if necessary, may have a discontinuous portion, for example, an externally open portion in a partial region. If necessary, the first cavity C1 may be provided as a plurality of first cavities C1, and the same or different electronic components 300 may be disposed in the respective first cavities C1. The thickness of the core layer 101 may be greater than the thickness of each of the build-up insulating layers that are to be disposed on one side and the other side of the core layer 101 later. An insulating material may be used as the material of the core layer 101, and a thermosetting resin such as an epoxy resin or a thermoplastic resin such as polyimide may be used as the insulating material. Further, as the insulating material, these resins containing an inorganic filler such as silica and a reinforcing material such as glass fibers may be used. For example, a prepreg may be used, but the insulating material is not limited thereto.

The heat dissipating member 200 may be embedded in the first cavity C1 of the core layer 101. The heat dissipating member 200 may include a carbon component, for example, a graphite or graphite material, useful for heat dissipation properties, and may also include a carbon fabric. For example, the heat dissipating member 200 may include a carbon fiber reinforced polymer (CFRP) formed of carbon fiber. Carbon fibers disposed in a horizontal direction may be included in the CFRP, and accordingly, when the heat dissipating member 200 includes CFRP, thermal conductivity in the horizontal direction may be improved, and thus, a heat dissipation effect may be improved. In the present disclosure, the meaning of the horizontal direction is not necessarily a direction orthogonal to the direction of gravity, but may indicate a direction orthogonal to the stacking direction in the electronic component-embedded substrate 100A, and does not mean a completely precise direction, but may mean an approximate direction within the range of a predetermined error. Depending on the arrangement direction of the carbon fibers in the heat dissipating member 200, the heat dissipating member 200 may further improve heat conduction in the horizontal direction. For example, heat generated in the electronic component-embedded substrate 100A may be more effectively discharged horizontally, thereby contributing to improving heat dissipation characteristics. The heat dissipating member 200 may have a three-dimensional block shape, but the shape thereof is not limited thereto. The second cavity C2 may be formed in the heat dissipating member 200. Unlike the shape of the first cavity C1 described above, the second cavity C2 may not penetrate through the entire heat dissipating member 200. For example, the second cavity C2 may have a blind cavity shape, and may be a space in which not only the four sides but also the lower surface thereof are closed. On the other hand, if necessary, the second cavity C2 may have a discontinuous portion, for example, an externally open portion in some areas. The second cavity C2 of the heat dissipating member 200 may be processed using a blast method, for example, sand blast, wet blast, micro blast, or the like, but the process method is not limited thereto.

On the other hand, when the heat dissipating member 200 includes CFRP, warpage of the entire substrate may be controlled due to the characteristic of CFRP having a low coefficient of thermal expansion (CTE).

The electronic component 300 may be an integrated circuit (IC) die in which hundreds to millions of devices are integrated into one chip. For example, the electronic component 300 may be a processor chip, in detail, an application processor (AP), such as a central processor (for example, a central processing unit (CPU)), a graphics processor (for example, a graphics processing unit (GPU)), a field programmable gate array (FPGA), a digital signal processor, a cryptographic processor, a microprocessor, a microcontroller, or the like. However, the electronic component 300 is not limited thereto, and for example, may also be a memory such as a volatile memory (for example, a dynamic random access memory (DRAM)), a non-volatile memory (for example, a read only memory (ROM)), a flash memory, or the like; or a logic circuit such as an analog-to-digital (ADC) converter, an application-specific integrated circuit (ASIC), or the like. If necessary, the electronic component 300 may also be a passive component in the form of a chip, for example, an inductor in the form of a chip or a capacitor in the form of a chip. The electronic component 300 may include a connection pad 300P, and may be disposed in such a manner that the surface on which the connection pad 300P is disposed faces the other surface of the core layer 101, and the opposite surface thereto faces one surface of the core layer 101. The connection pad 300P of the electronic component 300 may include a metal material such as copper (Cu), aluminum (Al) or the like, and may be connected to the second via 132.

At least a portion of the electronic component 300 may be disposed in the second cavity C2 of the heat dissipating member 200. Accordingly, the electronic component 300 may be completely embedded in the second cavity C2 depending on the size thereof, or a portion of the electronic component 300 may protrude outwardly of the second cavity C2. As illustrated in FIG. 3, the electronic component 300 may be directly attached to the inner portion of the second cavity C2 using an adhesive film 300T. On the other hand, the configuration of the adhesive film 300T may be omitted, and in this case, the second encapsulant 112 covers at least a portion of the electronic component 300 and fills a portion of the second cavity C2. Accordingly, the electronic component 300 may be attached in the second cavity C2 without a separate adhesive film. In this case, the electronic component 300 may physically contact the lower surface of the second cavity C2 of the heat dissipating member 200, and heat generated by the electronic component 300 may be conducted more efficiently.

On the other hand, as illustrated in FIG. 3, the width of the second cavity C2 may be greater than that of the electronic component 300. Accordingly, the inner wall of the second cavity C2 and the side surface of the electronic component 300 may be spaced apart by a predetermined distance, and the second encapsulant 112 may fill the gap therebetween. However, the present disclosure is not limited thereto, and the width of the second cavity C2 and the width of the electronic component 300 may be substantially the same, and the side of the second cavity C2 and the side of the electronic component 300 may physically contact each other. In this case, since the side surfaces of the heat dissipating member 200 and the electronic component 300 are in physical contact, heat generated by the electronic component 300 may be more effectively radiated externally.

The first and second encapsulants 111 and 112 may be disposed on one surface and the other surface of the core layer 101, respectively. In detail, the first encapsulant 111 may be disposed on one surface of the core layer 101 to cover at least a portion of each of the one surface of the core layer 101 and the one surface of the heat dissipating member 200. In addition, the first encapsulant 111 may fill at least a portion of the first cavity C1, and as a result, may cover at least a portion of each of one surface of the heat dissipating member 200 and a side surface thereof connected to the one surface. For example, the first encapsulant 111 may physically contact at least a portion of each of one surface and a side surface of the heat dissipating member 200. The second encapsulant 112 may be disposed on the other surface of the core layer 101 to cover at least portions of the other surface of the core layer 101 and the other surface of the heat dissipating member 200. In addition, the second encapsulant 112 may fill at least a portion of the second cavity C2, and as a result, may also cover at least a portion of each of the upper and side surfaces of the electronic component 300. For example, the second encapsulant 112 may physically contact at least a portion of each of the upper and side surfaces of the electronic component 300.

The material of the first and second encapsulants 111 and 112 is not particularly limited, but an insulating material may be used. For example, a thermosetting resin such as an epoxy resin or a thermoplastic resin such as polyimide may be used. In addition, a resin in which a reinforcing material such as glass fibers and/or inorganic fillers is impregnated in these resins, for example, prepreg, Ajinomoto Build-up Film (ABF), or the like may be used. In addition, a known molding material such as Epoxy Molding Compound (EMC) or the like may be used. In some embodiments, the warpage may be effectively reduced using a material comprising glass fibers and/or inorganic fillers and an insulating resin. ABF may be provided in the form of Resin Coated Copper (RCC), but is not limited thereto. If necessary, a photoimageable dielectric material such as Photo Image-able Dielectric (PID) may be used. In one example, the first and second encapsulants 111 and 112 may be made of different materials; however, the present disclosure is not limited thereto. For example, the first and second encapsulants 111 and 112 may be made of the same material. In this case, because the first and second encapsulants 111 and 112, as described later, may be formed in different processes, there may be a boundary or an interface between the first and second encapsulants 111 and 112.

On the other hand, the first and second encapsulants 111 and 112 may also include conductive particles to block electromagnetic waves. For example, the conductive particles may include copper (Cu), aluminum (Al), silver (Ag), tin (Sn), gold (Au), nickel (Ni), lead (Pb), or solder, but are not limited thereto.

The first and second wiring layers 121 and 122 may be disposed on one surface and the other surface of the core layer 101, respectively. At least portions of the first and second wiring layers 121 and 122 may be covered by the first and second encapsulants 111 and 112, respectively. In addition, the first and second wiring layers 121 and 122 may be electrically connected to the first and second vias 131 and 132 penetrating through at least portions of the first and second encapsulants 111 and 112, respectively. A metal material may be used as a material for the first and second wiring layers 121 and 122, and as the metal material, copper (Cu), aluminum (Al), silver (Ag), tin (Sn), gold (Au), nickel (Ni), lead (Pb), titanium (Ti), or alloys thereof may be used. The first and second wiring layers 121 and 122 may perform various functions according to a design, and for example, may include a ground pattern, a power pattern, a signal pattern, and the like. Each of these patterns may have a line, plane or pad shape. The first and second wiring layers 121 and 122 may be respectively formed by a plating process such as Additive Process (AP), Semi AP (SAP), Modified SAP (MSAP), Tenting (TT), or the like, and as a result, may each include a seed layer, which is an electroless plating layer, and an electrolytic plating layer formed on the basis of the seed layer. When the first and second wiring layers 121 and 122 are provided in the form of RCC, the first and second wiring layers 121 and 122 may further include a metal foil such as copper foil or the like, and, if necessary, a primer resin may be present on the surface of the metal foil.

The third and fourth wiring layers 123 and 124 may be disposed on the first and second encapsulants 111 and 112, respectively. The third and fourth wiring layers 123 and 124 may be electrically connected to the first and second wiring layers 121 and 122 through the first and second vias 131 and 132 penetrating through at least portions of the first and second encapsulants 111 and 112, respectively. A metal material may be used as a material for the third and fourth wiring layers 123 and 124, and as the metal material, copper (Cu), aluminum (Al), silver (Ag), tin (Sn), gold (Au), nickel (Ni), lead (Pb), titanium (Ti), or alloys thereof may be used. The third and fourth wiring layers 123 and 124 may perform various functions according to a design, and for example, may include a ground pattern, a power pattern, a signal pattern, and the like. Each of these patterns may have a line, plane or pad shape. The third and fourth wiring layers 123 and 124 may be respectively formed by a plating process such as Additive Process (AP), Semi AP (SAP), Modified SAP (MSAP), Tenting (TT), or the like, and as a result, may each include a seed layer, which is an electroless plating layer, and an electrolytic plating layer formed on the basis of the seed layer. When the third and fourth wiring layers 123 and 124 are provided in the form of an RCC, the third and fourth wiring layers 123 and 124 may further include a metal foil such as copper foil, and if necessary, a primer resin may be present on the surface of the metal foil.

The first and second vias 131 and 132 may penetrate through at least portions of the first and second encapsulants 111 and 112, respectively. The first via 131 may electrically connect the first and third wiring layers 121 and 123, and at least a portion of the second via 132 may electrically connect the second and fourth wiring layers 122 and 124. On the other hand, at least another portion of the second via 132 may electrically connect the fourth wiring layer 124 and the connection pad 300P of the electronic component 300. In this case, the heights and/or diameters of the second via 132 connected to the second wiring layer 122 and the second via 132 connected to the connection pad 300P of the electronic component 300 may be different from each other. A metal material may be used as a material for the first and second vias 131 and 132, and as the metal material, copper (Cu), aluminum (Al), silver (Ag), tin (Sn), gold (Au), nickel (Ni), lead (Pb), titanium (Ti), or alloys thereof may be used. The first and second vias 131 and 132 may include a signal via, a ground via, a power via, or the like according to a design. The first and second vias 131 and 132 may be respectively formed by completely filling a via hole with a metal material, or forming a metal material along a wall surface of the via hole. The first and second vias 131 and 132 may also be formed by a plating process, for example, AP, SAP, MSAP, TT, or the like, and may include a seed layer as an electroless plating layer, and an electrolytic plating layer formed based on the seed layer. The first and second vias 131 and 132 may have a tapered shape in which the width of one surface is greater than the width of the other surface, and the first and second vias 131 and 132 may have shapes tapered in opposite directions.

On the other hand, although not illustrated, to form various wiring paths in the electronic component-embedded substrate 100A, a build-up structure may be additionally disposed on at least a portion of one surface and the other surface of the electronic component-embedded substrate 100A. The build-up structure may include a plurality of insulating layers, a plurality of wiring layers, and a plurality of via layers. On the other hand, the build-up structures do not necessarily have to be symmetrically stacked on one surface of the core layer 101 and the other surface of the core layer 101, and may be stacked with different numbers of layers to have an asymmetric structure, if necessary. For example, the number of the plurality of insulating layers disposed on one surface of the electronic component-embedded substrate 100A and the number of the plurality of insulating layers disposed on the other surface thereof may be different from each other, and accordingly, the number of the plurality of wiring layers and the number of the plurality of via layers may also be different from each other.

As a material for the plurality of insulating layers, an insulating material may be used, and a thermosetting resin such as an epoxy resin or a thermoplastic resin such as polyimide may be used as the insulating material. Further, these resins containing an inorganic filler such as silica and a reinforcing material such as glass fibers may be used. For example, a prepreg may be used as a material for the plurality of insulating layers, but the material thereof is not limited thereto. For example, a material not including a reinforcing material such as glass fiber, for example, ABF, or the like may be used. If necessary, a photoimageable dielectric material such as PID may be used.

A metal material may be used as a material for the plurality of wiring layers, and as the metal material, copper (Cu), aluminum (Al), silver (Ag), tin (Sn), gold (Au), nickel (Ni), lead (Pb), titanium (Ti), or alloys thereof may be used.

A metal material may be used as a material for the plurality of via layers, and as the metal material, copper (Cu), aluminum (Al), silver (Ag), tin (Sn), gold (Au), nickel (Ni), lead (Pb), titanium (Ti), or alloys thereof may be used.

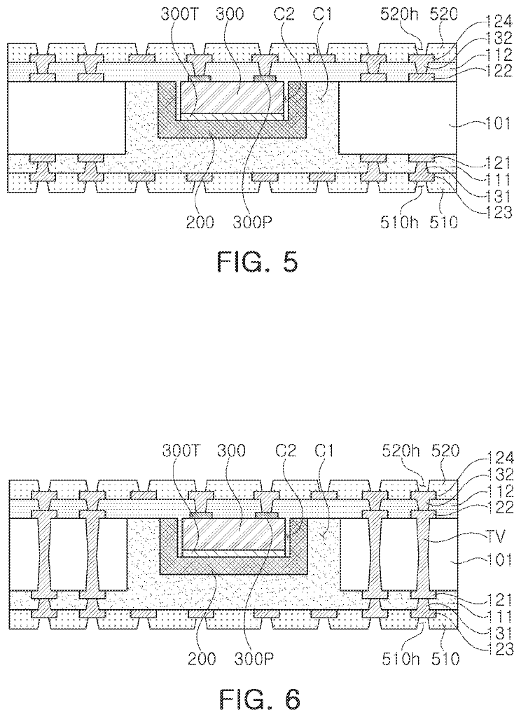

FIG. 5 is a schematic cross-sectional view illustrating a structure in which a passivation layer is further disposed on the electronic component-embedded substrate of FIG. 3.

FIG. 6 is a schematic cross-sectional view illustrating a structure in which through-vias are further disposed on the electronic component-embedded substrate of FIG. 5.

The first and second passivation layers 510 and 520 may protect internal components from external physical and chemical damage. The first and second passivation layers 510 and 520 may have a plurality of first and second openings 510h and 520h, respectively. The plurality of first openings 510h may respectively expose at least a portion of the third wiring layer 123. The plurality of second openings 520h may respectively expose at least a portion of the fourth wiring layer 124. The material of the first and second passivation layers 510 and 520 may be an insulating material. In this case, the insulating material may be a thermosetting resin such as epoxy resin, a thermoplastic resin such as polyimide, or a mixture of these resins with an inorganic filler, for example, ABF may be used, but is not limited thereto, and a photoimageable dielectric material such as PID may be used if necessary. Therefore, internal components may be protected from physical and chemical damage or the like.

On the other hand, when the build-up structure is disposed on the electronic component-embedded substrate 100A, the first and second passivation layers 510 and 520 are disposed on an outermost layer of the build-up structure, to expose a circuit layer disposed on the outermost layer.

On the other hand, an electrical connection metal may be disposed in the exposed first and second openings 510h and 520h of the first and second passivation layers 510 and 520, such that the electronic component-embedded substrate 100A may be mounted on other electronic component-embedded substrates such as a main board or an additional Ball Grid Array (BGA) board, and surface-mounted components may be surface mounted. When the surface-mounted component is further disposed, the electronic component-embedded substrate 100A may be used as a package module, for example, a System in Package (SiP). The electrical connection metal may be formed of tin (Sn) or an alloy containing tin (Sn), for example, solder or the like, but is not limited thereto. The electrical connection metal may be a land, a ball, or a pin.

Other contents are substantially the same as described above, and overlapping descriptions will be omitted.

Referring to FIG. 6, a structure in which a through-via (TV) is further disposed in the electronic component-embedded substrate of FIG. 5 is illustrated. The through-via (TV) may penetrate through the core layer 101 and may electrically connect the first and second wiring layers 121 and 122. The through-via (TV) may be formed in the core layer 101 through laser processing or the like, and may have an hourglass shape at the time of performing double-sided processing, but the shape thereof is not limited thereto. For example, in some cases, the through-via (TV) may have a shape tapered in one direction.

A metal material may be used as a material for the through-via (TV), and as the metal material, copper (Cu), aluminum (Al), silver (Ag), tin (Sn), gold (Au), nickel (Ni), lead (Pb), titanium (Ti), or alloys thereof may be used. The through-via (TV) may include a signal via, a ground via, a power via, or the like according to a design. The through-vias TV may be respectively formed by completely filling a via hole with a metal material, or forming a metal material along a wall surface of the via hole. The through-via (TV) may also be formed by a plating process, for example, AP, SAP, MSAP, TT, or the like, and may include a seed layer, which is an electroless plating layer, and an electroplating layer formed based on the seed layer. In addition thereto, redundant description will be omitted.

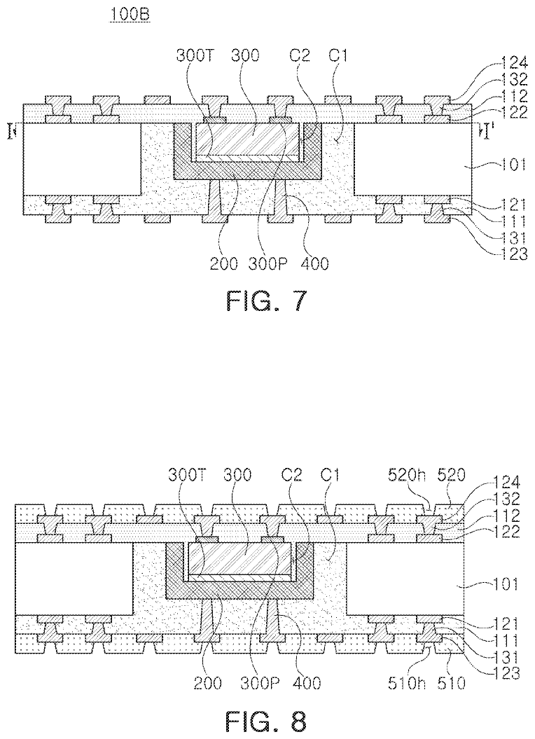

FIG. 7 is a schematic cross-sectional view of another example of an electronic component-embedded substrate.

An electronic component-embedded substrate 100B according to a second embodiment in FIG. 7 is different from the electronic component-embedded substrate 100A according to the first embodiment in that a heat dissipation via 400 is further disposed. Therefore, in the description of the electronic component-embedded substrate 100B according to the second embodiment below, differences are mainly described as compared to the electronic component-embedded substrate 100A according to the first embodiment, and descriptions of other overlapping configurations may be replaced with the description of the electronic component-embedded substrate 100A according to the first embodiment in the same manner.

Referring to FIG. 7, a heat dissipation via 400 penetrating through at least a portion of the first encapsulant 111 may be further disposed. When the thickness of the heat dissipating member 200 is less than that of the core layer 101, the heat dissipation via 400 may penetrate through a portion of the first cavity C1. The heat dissipation via 400 may be processed through a mechanical method such as laser drilling or a blast method. In detail, to prevent damage to the CFRP material in the heat dissipating member 200, a blast process may be used. The heat dissipation via 400 may have a tapered shape in which a cross-sectional area decreases from one side toward the other side.

In detail, the radiating via 400 may have a tapered shape in which a width of an end surface thereof in contact with the third wiring layer 123 of the electronic component-embedded substrate 100B is greater than a width of an end surface thereof in contact with the heat radiating member 200.

The heat dissipation via 400 may be filled with a metallic material, such that one end thereof may be electrically connected to at least a portion of the third wiring layer 123. On the other hand, the other end of the heat dissipation via 400 may contact the heat dissipating member 200. In this case, the width of one end of the heat dissipation via 400 may be greater than the width of the other end. In addition, in addition to the heat dissipating member 200 having high thermal conductivity in the horizontal direction, an effect of improving heat dissipation characteristics in the vertical direction may be obtained due to the arrangement of the heat dissipation via 400. A signal may not be transmitted to the third wiring layer 123 connected to the heat dissipation via 400 to perform a heat dissipation function. Since the heat dissipation via 400 is disposed in the stacking direction or in the thickness direction of the electronic component-embedded substrate 100B, heat dissipation characteristics in the stacking direction or the thickness direction of the electronic component-embedded substrate 100B may be improved.

For example, in the case of the electronic component-embedded substrate 100B, the heat dissipation characteristics in the horizontal direction may be improved by the heat dissipating member 200, and the heat dissipation characteristics in the stacking direction may be improved by the heat dissipation vias 400.

A metal material may be used as a material of the heat dissipation via 400, and as the metal material, copper (Cu), aluminum (Al), silver (Ag), tin (Sn), gold (Au), nickel (Ni), lead (Pb), titanium (Ti), or alloys thereof may be used. The heat dissipation via 400 may include a signal via, a ground via, a power via, or the like according to a design. The heat dissipation vias 400 may be formed as the via holes are completely filled with a metal material or formed as a metal material is formed along the wall surfaces of the via holes. The heat dissipation via 400 may also be formed by a plating process, for example, AP, SAP, MSAP, TT, or the like, and may include a seed layer, which is an electroless plating layer, and an electrolytic plating layer formed based on the seed layer. In addition, redundant descriptions will be omitted.

The heat dissipation vias 400 may be in contact with one surface of the heat dissipating member 200 and may include a plurality of vias spaced apart from each other, to penetrate through the first encapsulant 111, thereby performing a function of dissipating heat from the heat dissipating member 200 in the stacking direction of the electronic component-embedded substrate 100B. On the other hand, although not illustrated, the heat dissipation via 400 may have a bar-via shape in which a plurality of vias partially overlap each other, and may also have a shape in which a plurality of vias are connected to each other to be in contact with one surface of the heat dissipating member 200.

FIG. 8 is a schematic cross-sectional view illustrating a structure in which a passivation layer is further disposed on the electronic component-embedded substrate of FIG. 7.

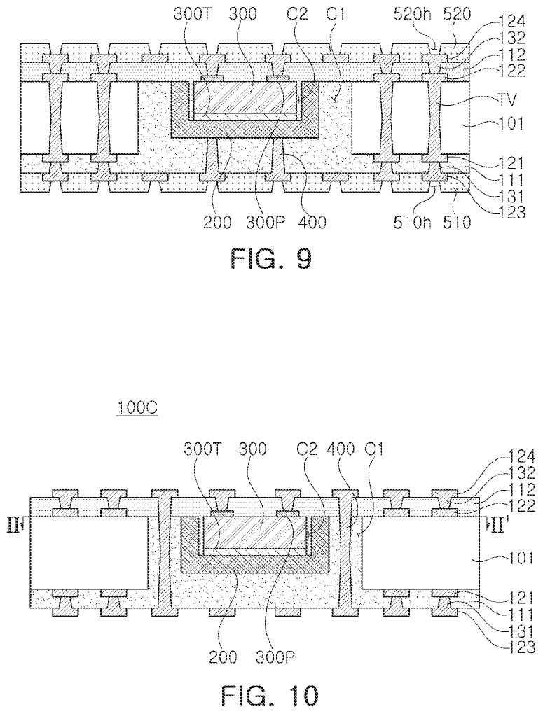

FIG. 9 is a schematic cross-sectional view illustrating a structure in which through-vias are further disposed on the electronic component-embedded substrate of FIG. 8.

Referring to FIG. 8, in the electronic component-embedded substrate 100B according to the second embodiment, first and second passivation layers 510 and 520 having first and second openings 510h and 520h may be disposed, and the descriptions of the first and second passivation layers 510 and 520, an electrical connection metal disposed in the first and second openings 510h and 520h, and surface mount components are the same as in the electronic component-embedded substrate 100A according to the first embodiment, and thus, will be omitted.

On the other hand, referring to FIG. 9, a through-via TV may be formed in the electronic component-embedded substrate 100B according to the second embodiment, and since the through-via TV has been described above, the description will be omitted.

FIG. 10 is a schematic cross-sectional view of another example of an electronic component-embedded substrate.

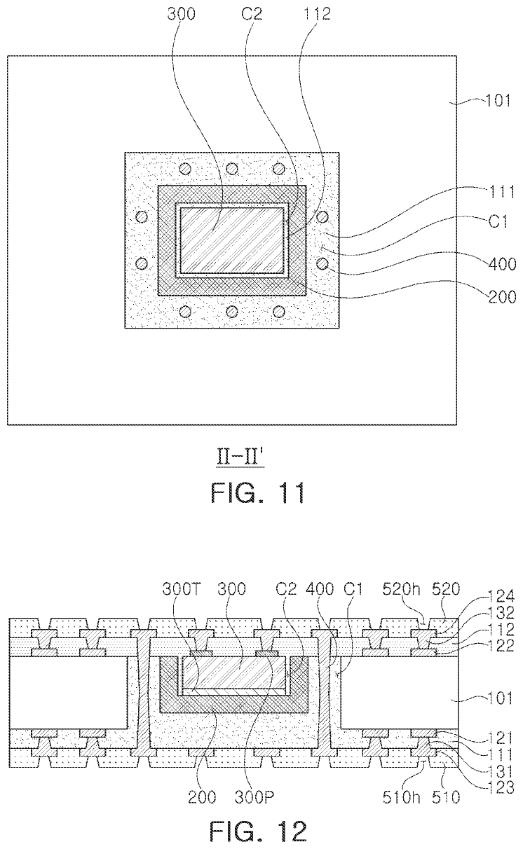

FIG. 11 is a schematic cutaway plan view of the electronic component-embedded substrate, taken along line II-II′ of FIG. 10.

Compared with the electronic component-embedded substrate 100B according to the second embodiment, an electronic component-embedded substrate 100C according to a third embodiment of FIG. 10 has a difference in that a heat dissipation via 400 is disposed adjacent to the side surface of the heat dissipation member 200. Therefore, in the following description of the electronic component-embedded substrate 100C according to the third embodiment, differences are mainly described compared to the electronic component-embedded substrate 100B according to the second embodiment, and for other overlapping configurations, the description of the electronic component-embedded substrate 100B according to the second embodiment may be applied in the same manner.

Referring to the electronic component-embedded substrate 100C according to the third embodiment of FIG. 10, the heat dissipation via 400 may be formed to penetrate through the first and second encapsulants 111 and 112. Accordingly, the heat dissipation via 400 may further penetrate through the first cavity C1, and compared with the electronic component-embedded substrate 100B according to the second embodiment, the heat dissipation via 400 of the electronic component-embedded substrate 100C according to the third embodiment may completely penetrate through the first cavity C1.

Referring to FIGS. 10 and 11, the heat dissipation via 400 may be disposed to be spaced apart from the heat dissipating member 200 by a predetermined distance, and may be processed through a mechanical method such as laser drilling or a blast method. Unlike in the electronic component-embedded substrate 100B according to the second embodiment, the heat dissipation via 400 may have an hourglass shape in which the cross-sectional area near the center is smaller than the cross-sectional area of one end and the other end. If necessary, the heat dissipation via 400 may have a tapered shape in which a cross-sectional area decreases from one side toward the other side, as in the electronic component-embedded substrate 100B according to the second embodiment.

The heat dissipation via 400 may be filled with a metallic material therein to electrically connect at least portions of the third and fourth wiring layers 123 and 124 to each other. Signals may not be transmitted to each of the third and fourth wiring layers 123 and 124 connected to the heat dissipation via 400 to perform a heat dissipation function. Since the heat dissipation via 400 is disposed in the stacking direction or the thickness direction of the electronic component-embedded substrate 100C, heat dissipation characteristics in the stacking direction or the thickness direction of the electronic component-embedded substrate 100C may be improved.

Referring to FIG. 11, the heat dissipation via 400 may be provided as a plurality of heat dissipation vias 400 to surround a side surface of the heat dissipating member 200 and to be spaced apart from the heat dissipating member 200 by a predetermined distance. Therefore, for example, when the heat conducted to the side surface of the heat dissipating member 200 is conducted to the first encapsulant 111 through the heat dissipation member 200 for dissipation of heat in the horizontal direction, a function of dissipating heat in the stacking direction of the electronic component-embedded substrate 100C again may be performed through the heat dissipation via 400. On the other hand, although not illustrated, the heat dissipation via 400 may have a bar-via shape in which a plurality of vias partially overlap each other, and may also have a shape in which a plurality of vias are connected to each other to surround the heat dissipating member 200.

FIG. 12 is a schematic cross-sectional view illustrating a structure in which a passivation layer is further disposed on the electronic component-embedded substrate of FIG. 10.

Referring to FIG. 12, first and second passivation layers 510 and 520 having first and second openings 510h and 520h may be disposed in the electronic component-embedded substrate 100C according to the third embodiment. The first and second passivation layers 510 and 520, the electrical connection metal disposed in the first and second openings 510h and 520h, and the surface-mounted components are the same as those in the electronic component-embedded substrate 100A according to the first embodiment, and thus, descriptions thereof will be omitted.

On the other hand, as illustrated in FIG. 12, at least portions of the third and fourth wiring layers 123 and 124 may respectively be connected to the heat dissipation via 400. However, as illustrated in FIG. 12, regions of the third and fourth wiring layers 123 and 124, connected to the heat dissipation via 400, do not necessarily have to be exposed through the first and second openings 510h and 520h. For example, one wiring layer may be exposed through the first or second openings 510h and 520h, and the other wiring layer may be covered by the first or second passivation layers 510 and 520. For example, although not illustrated, there may be provided a structure in which the third wiring layer 123 connected to the heat dissipation via 400 is covered by the first passivation layer 510 and is not exposed externally, and the fourth wiring layer 124 connected to the heat dissipation via 400 is exposed externally through the second opening 520h formed in the second passivation layer 520.

In this case, the main heat dissipation path inside of the component may be selectively designed, and in consideration of the relationship with other surrounding components such as the surface-mounted component or the main board, the degree of freedom in product design may be improved in terms of setting the direction in which heat generated by the electronic component 300 is mainly radiated.

The asymmetrical exposed structure of the wiring layer connected to the heat dissipation via 400 may be equally applied to the electronic component-embedded substrate according to another example to be described below.

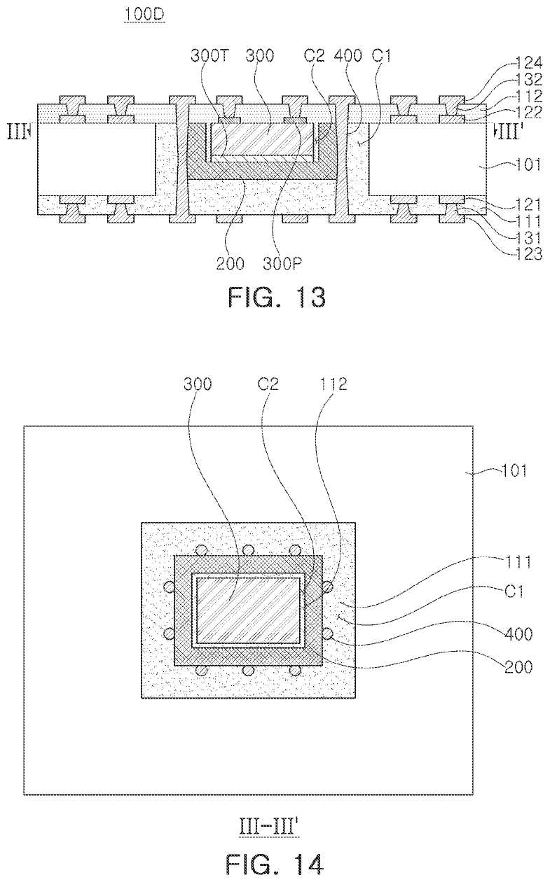

FIG. 13 is a schematic cross-sectional view of another example of an electronic component-embedded substrate.

An electronic component-embedded substrate 100D according to a fourth embodiment in FIG. 13 has a difference from the electronic component-embedded substrate 100C according to the third embodiment, in that the heat dissipation via 400 is disposed to be in contact with the heat dissipating member 200. Therefore, in the following description of the electronic component-embedded substrate 100D according to the fourth embodiment, the differences are mainly described compared to the electronic component-embedded substrate 100C according to the third embodiment, and for other overlapping configurations, the description of the electronic component-embedded substrate 100C according to the third embodiment may be applied in the same manner.

According to the electronic component-embedded substrate 100D according to the fourth embodiment, the heat dissipation via 400 may be disposed to contact the heat dissipating member 200. For example, when a plating layer formed of a metal material inside of the heat dissipation via 400 contacts the heat dissipating member 200, the heat dissipation effect in the horizontal direction and the vertical direction “W” may be further increased. The vertical direction in the present disclosure refers to substantially the same direction as the thickness direction or the stacking direction of the electronic component-embedded substrate 100D, and may indicate a direction allowing a predetermined error range even if not necessarily the same.

FIG. 14 is one example of a schematic plan view taken along line III-III′ of the electronic component-embedded substrate of FIG. 13.

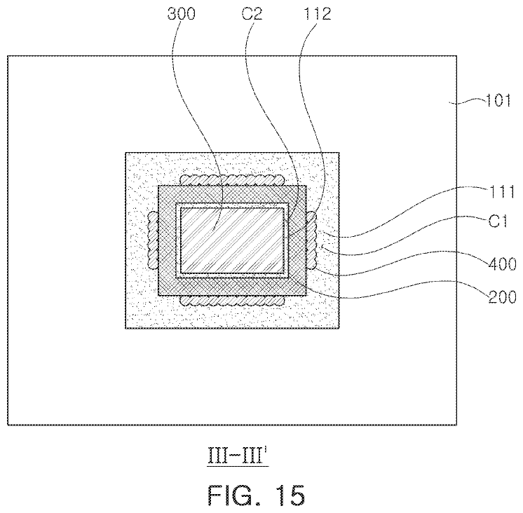

FIG. 15 is another example of a schematic plan view taken along line III-III′ of the electronic component-embedded substrate of FIG. 13.

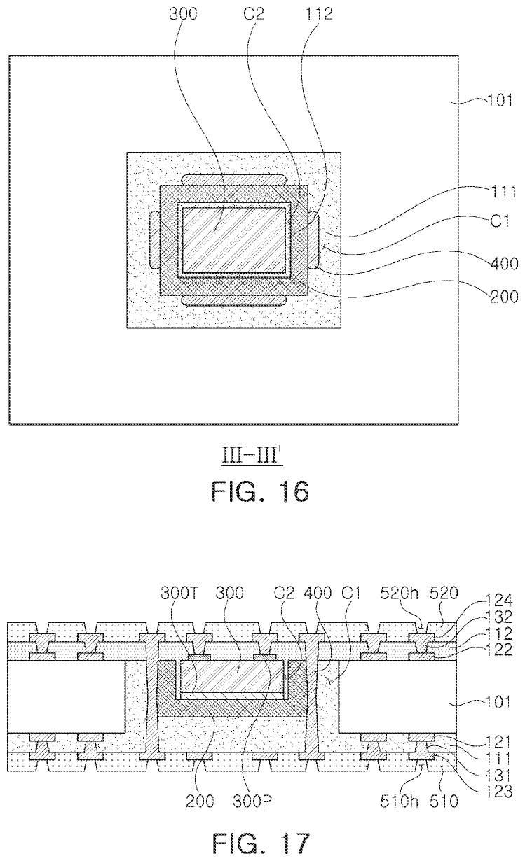

FIG. 16 is another example of a schematic plan view taken along line III-III′ of the electronic component-embedded substrate of FIG. 13.

FIGS. 14 to 16 are plan views illustrating shapes that the heat dissipation via 400 of the electronic component-embedded substrate 100D according to the fourth embodiment may have, as examples.

Referring to FIG. 14, a plurality of heat dissipation vias 400 may be disposed to surround the side surface of the heat dissipating member 200 while contacting the side surface of the heat dissipating member 200. In this structure, the plurality of heat dissipation vias 400 may be disposed to be spaced apart from each other by a predetermined distance, while the heat dissipation vias 400 may respectively contact the side surface of the heat dissipating member 200. For example, the heat dissipating member 200 may be exposed from the inner walls of the respective heat dissipation vias 400 to be electrically connected to the metallic material inside of the heat dissipation vias 400. In this case, the carbon fiber for heat conduction in the horizontal direction in the heat dissipating member 200, and the plating layer for heat conduction in the vertical direction in the heat dissipation via 400, may be in contact with each other. Therefore, the heat dissipation characteristics of the electronic component-embedded substrate 100D may be further, significantly increased.

Referring to FIG. 15, the heat dissipation vias 400 may be formed to have a bar-via shape in which at least portions of a plurality of heat dissipation vias 400 overlap each other. For example, at least portions of the heat dissipation vias 400 may be disposed in such a manner that cross-sectional areas of a plurality of heat dissipation vias 400 are overlapped and a side surface of the heat dissipating member 200 is exposed to inner walls of the overlapped heat dissipation vias 400. In this case, accordingly, a cross-sectional area may be wider than that of the structure in which the plurality of heat dissipation vias 400 are spaced apart from each other, and resistance may be reduced during heat conduction, and thus heat dissipation characteristics may be further improved.

Referring to FIG. 16, the heat dissipation via 400 may have a structure in which a plurality of bar-vias are in contact with the side surface of the heat dissipating member 200. The heat dissipation vias 400 of FIG. 16 may have a structure in which the respective heat dissipation vias 400 extend by a predetermined distance, compared to the heat dissipation vias 400 of FIG. 15. The side surface of the heat dissipating member 200 may be exposed through the inner wall of the bar-via-shaped heat dissipation via 400, and the exposed area of the heat dissipating member 200 may increase due to the bar-via shape. Accordingly, heat dissipation characteristics in the horizontal/vertical directions may be further improved.

FIG. 17 is a schematic cross-sectional view illustrating a structure in which a passivation layer is further disposed on the electronic component-embedded substrate of FIG. 13.

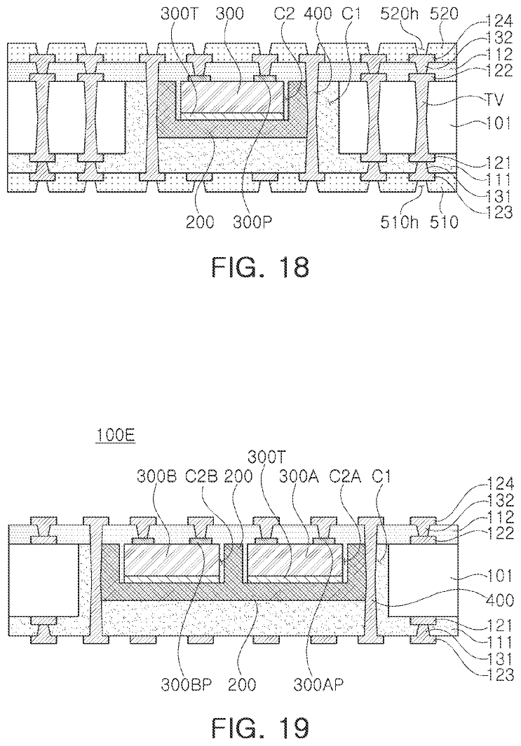

FIG. 18 is a schematic cross-sectional view illustrating a structure in which through-vias are further disposed on the electronic component-embedded substrate of FIG. 17.

Referring to FIG. 17, first and second passivation layers 510 and 520 having first and second openings 510h and 520h may be disposed in the electronic component-embedded substrate 100D according to the fourth embodiment. Descriptions of the first and second passivation layers 510 and 520, the electrical connection metal disposed in the first and second openings 510h and 520h, and the surface mounted components have been described above, and thus, the descriptions thereof will be omitted.

On the other hand, referring to FIG. 18, a through-via TV may be formed in the electronic component-embedded substrate 100D according to the fourth embodiment, and a description of the through-via TV has been described above, and thus will be omitted.

FIG. 19 is a schematic cross-sectional view of another example of an electronic component-embedded substrate.

An electronic component-embedded substrate 100E according to a fifth embodiment in FIG. 19 has a difference in that a plurality of second cavities C2A and C2B are formed in the heat dissipating member 200 and a plurality of electronic components 300A and 300B are embedded in the second cavities C2A and C2B respectively, compared with those in the electronic component-embedded substrate 100D according to the fourth embodiment. Therefore, in the following description of the electronic component-embedded substrate 100E according to the fifth embodiment, the differences will be mainly described, compared to the electronic component-embedded substrate 100D according to the fourth embodiment, and descriptions of overlapping configurations may be replaced with the descriptions of the electronic component-embedded substrate 100D according to the fourth embodiment.

Referring to FIG. 19, the plurality of second cavities C2A and C2B may be formed in the heat dissipating member 200. Accordingly, the plurality of electronic components 300A and 300B may be disposed in the second cavities C2A and C2B, respectively, so that electronic components performing more various functions may be embedded in the electronic component-embedded substrate 100E. Connection pads 300AP and 300BP are disposed in the electronic components 300A and 300B, respectively, to be electrically connected to at least portions of the fourth wiring layers 124 through the second vias 132.

Similarly, the electronic component-embedded substrate 100E according to the fifth embodiment may also have a structure in which the heat dissipating member 200 and the heat dissipation via 400 are in contact with each other, to expose the side surface of the heat dissipating member 200 to the inner wall of the heat dissipation via 400. Accordingly, heat generated by the plurality of electronic components 300A and 300B may be effectively transferred in the horizontal/vertical direction.

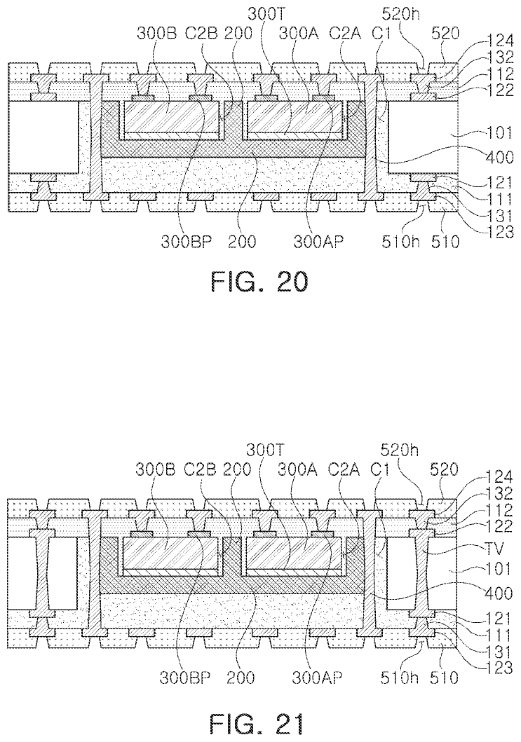

FIG. 20 is a schematic cross-sectional view illustrating a structure in which a passivation layer is further disposed on the electronic component-embedded substrate of FIG. 19.

FIG. 21 is a schematic cross-sectional view illustrating a structure in which through-vias are further disposed on the electronic component-embedded substrate of FIG. 20.

Referring to FIG. 20, first and second passivation layers 510 and 520 having first and second openings 510h and 520h may be disposed in the electronic component-embedded substrate 100E according to the fifth embodiment. Descriptions of the first and second passivation layers 510 and 520, the electrical connection metal disposed in the first and second openings 510h and 520h, and the surface mount components have been provided above, and thus will be omitted.

On the other hand, referring to FIG. 21, a through-via TV may be formed in the electronic component-embedded substrate 100E according to the fifth embodiment, and a description of the through-via TV has been described above, and thus will be omitted.

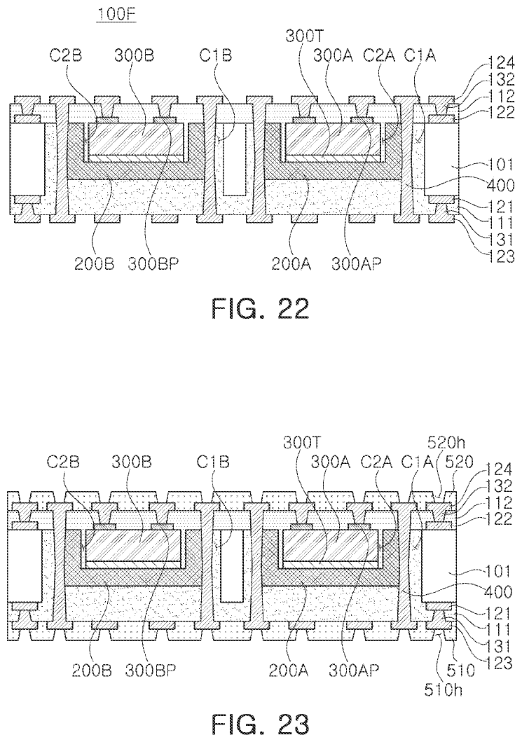

FIG. 22 is a schematic cross-sectional view of another example of an electronic component-embedded substrate.

Compared with the electronic component-embedded substrate 100D according to the fourth embodiment, an electronic component-embedded substrate 100F according to a sixth embodiment in FIG. 22 has a difference in that a plurality of first cavities C1A and C1B are formed in the core layer 101, heat radiating members 200A and 200B are disposed in the first cavities C1A and C1B, respectively, and a plurality of electronic components 300A and 300B are embedded in second cavities C2A and C2B of the plurality of heat dissipating members 200A and 200B, respectively. Therefore, in the following description of the electronic component-embedded substrate 100F according to the sixth embodiment, differences are mainly described compared to the electronic component-embedded substrate 100D according to the fourth embodiment, and for other overlapping configurations, the description of those of the electronic component-embedded substrate 100D according to the fourth embodiment may be applied in the same manner.

Referring to FIG. 22, the plurality of first cavities C1A and C1B spaced apart from each other may be formed in the core layer 101. The plurality of first cavities C1A and C1B may respectively penetrate through the core layer 101, and the same description as the above-described first cavity C1 may be applied thereto.

In the plurality of first cavities C1A and C1B, the heat dissipating members 200A and 200B may be embedded, respectively. The second cavities C2A and C2B may be formed in the heat dissipating members 200A and 200B, respectively, and the electronic components 300A and 300B may be disposed in the plurality of second cavities C2A and C2B, respectively. The plurality of electronic components 300A and 300B may include connection pads 300AP and 300BP, respectively, and the connection pads 300AP and 300BP may be electrically connected to the fourth wiring layers 124 through the second vias 132.

Similarly, in the electronic component-embedded substrate 100F according to the sixth embodiment, the heat dissipating member 200 and the heat dissipation via 400 may also have a structure in which they are in contact with each other in such a manner that the side surface of the heat dissipating member 200 is exposed to the inner wall of the heat dissipation via 400.

Referring to FIG. 22, the heat dissipation vias 400 may be disposed to surround side surfaces of the plurality of heat dissipating members 200A and 200B, and thus, heat generated by the electronic components 300A and 300B may be effectively transferred.

Accordingly, in the case of the electronic component-embedded substrate 100F according to the sixth embodiment, the electronic components 300A and 300B capable of performing various functions may be embedded, and simultaneously, the electronic component-embedded substrate 100F may be miniaturized and relatively thinned, and heat dissipation characteristics may be improved such that heat generated by the plurality of electronic components 300A and 300B may be efficiently discharged in horizontal and vertical directions.

FIG. 23 is a schematic cross-sectional view illustrating a structure in which a passivation layer is further disposed on the electronic component-embedded substrate of FIG. 22.

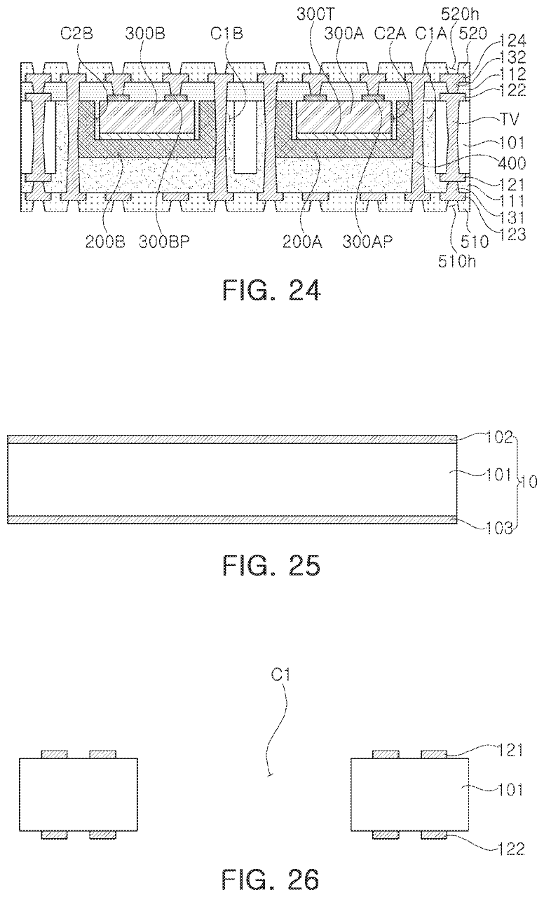

FIG. 24 is a schematic cross-sectional view illustrating a structure in which through-vias are further disposed on the electronic component-embedded substrate of FIG. 23.

Referring to FIG. 23, in the electronic component-embedded substrate 100F according to the sixth embodiment, first and second passivation layers 510 and 520 having first and second openings 510h and 520h may be disposed. Descriptions of the first and second passivation layers 510 and 520, the electrical connection metal disposed in the first and second openings 510h and 520h, and the surface mount components have been provided above, and thus will be omitted.

On the other hand, referring to FIG. 24, a through-via TV may be formed in the electronic component-embedded substrate 100F according to the sixth embodiment, and a description of the through-via TV has been described above, and thus will be omitted.

FIGS. 25 to 34 are cross-sectional views schematically illustrating an example of manufacturing the electronic component-embedded substrate of FIG. 13.

Referring to FIG. 25, first, a copper clad laminate 10 (CCL) in which copper foils 102 and 103 are disposed on at least one surface of the core layer 101 is prepared.

Referring to FIG. 26, the first and second wiring layers 121 and 122 are formed on one surface and the other surface of the core layer 101 by performing an electroless/electrolytic plating process and a patterning process on the copper foils 102 and 103. The patterning process may be performed through an exposure/development process of the related art, and the method thereof is not particularly limited. When electroless plating is performed, the first and second wiring layers 121 and 122 may include a seed layer, and copper foils 102 and 103 may function as seed layers.

After the first and second wiring layers 121 and 122 are disposed, a first cavity C1 may be formed in the core layer 101. The first cavity C1 may be formed by laser processing, mechanical processing, or the like, and in this case, a CO₂ laser, a YAG laser, or Computer Numerical Control (CNC) drilling may be used, and a blast method may also be used. Any method, by which the core layer 101, which is a relatively thick insulating layer, may be penetrated, may be used without limitation.

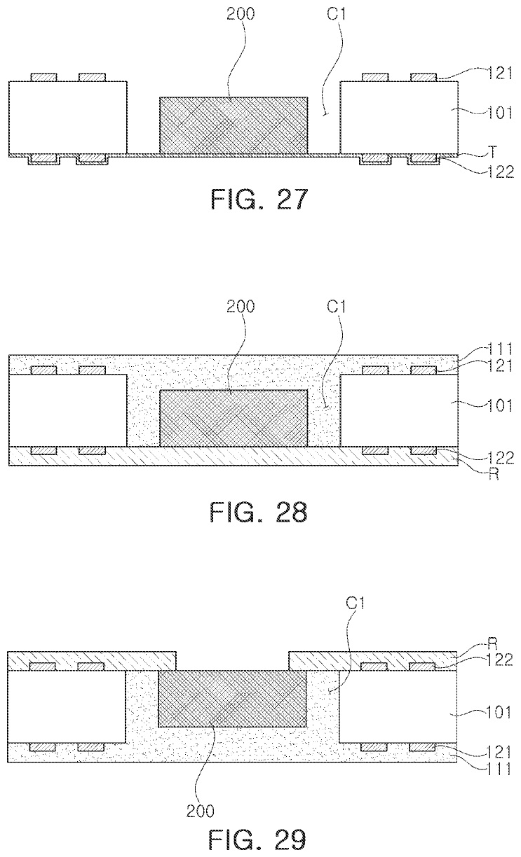

Referring to FIG. 27, the heat dissipating member 200 may be disposed in the first cavity C1 by using a tape T.

Referring to FIG. 28, a first encapsulant 111 covering one surface of the core layer 101 and filling the first cavity C1 is disposed, and after peeling the tape T, resist R may be disposed on a position from which the tape has been peeled off. When the first encapsulant 111 is disposed, an insulating material of the first encapsulant 111 may be in an uncured or semi-cured state. Accordingly, the fluidity or flowability of the insulating material is relatively high, and the remaining space of the first cavity C1 may be filled therewith, and then, the insulating material may be cured through a curing treatment.

The resist R may be disposed to cover the other surface of the core layer 101 and at least portions of the first encapsulant 111 and the heat dissipating member 200, and a photosensitive insulating film such as a dry film resist may be used.

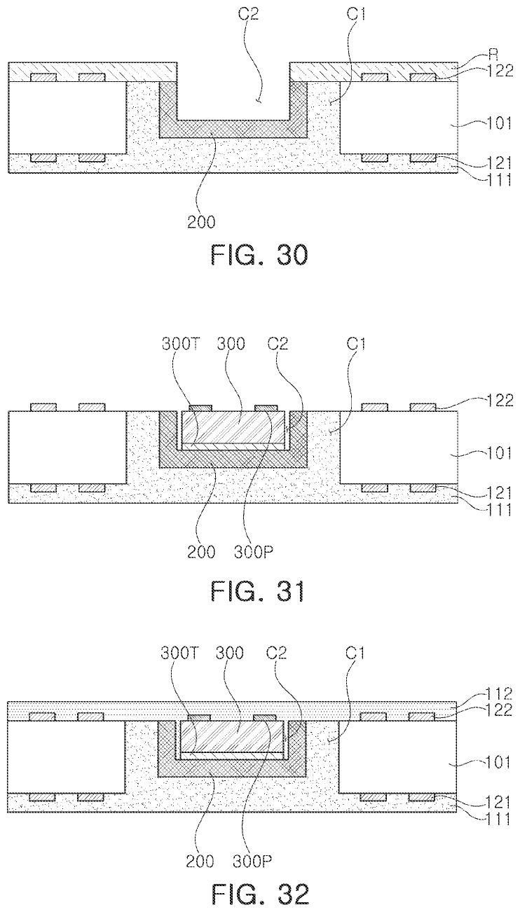

Referring to FIGS. 29 and 30, an opening may be formed in the resist R through exposure and development processes, and a second cavity C2 may be formed in the heat dissipating member 200 exposed through the opening, through a blast process. As the blasting process, a general blasting process may be used without particular limits, and for example, sand blasting, wet blasting, or the like may be used.

As the second cavity C2 of the heat dissipating member 200 is formed by a blasting process, damage to the carbon fibers inside of the heat dissipating member 200 may be prevented, compared to a mechanical processing method such as laser processing. For example, the carbon fiber disposed inside of the heat dissipating member 200 in a substantially horizontal direction may be damaged during processing by a mechanical processing method such as laser processing, whereas when the heat dissipating member 200 is processed by a blasting process, the thermal conductivity in the horizontal direction may be improved by significantly reducing damage to the carbon fiber inside of the heat dissipating member 200.

Referring to FIGS. 31 and 32, the electronic component 300 provided with the connection pad 300P is attached in the second cavity C2 using an adhesive film 300T, and then, a second encapsulant 112 may be disposed to fill at least a portion of the second cavity C2 while covering the other surface of the core layer 101. When the second encapsulant 112 is disposed, the insulating material of the second encapsulant 112 may be in an uncured or semi-cured state. Accordingly, the fluidity or flowability thereof is relatively high, and thus, the remaining space of the second cavity C2 may be filled with the insulating material, to then be cured through a curing treatment.

On the other hand, as the adhesive film 300T, a die attach film (DAF) of the related art may be used, and the adhesive film 300T is a configuration that may be omitted. The electronic component 300 may be fixed through the curing treatment of the second encapsulant 112 without the adhesive film 300T. In this case, since the electronic component 300 and the heat dissipating member 200 contact each other, heat dissipation characteristics may be further improved.

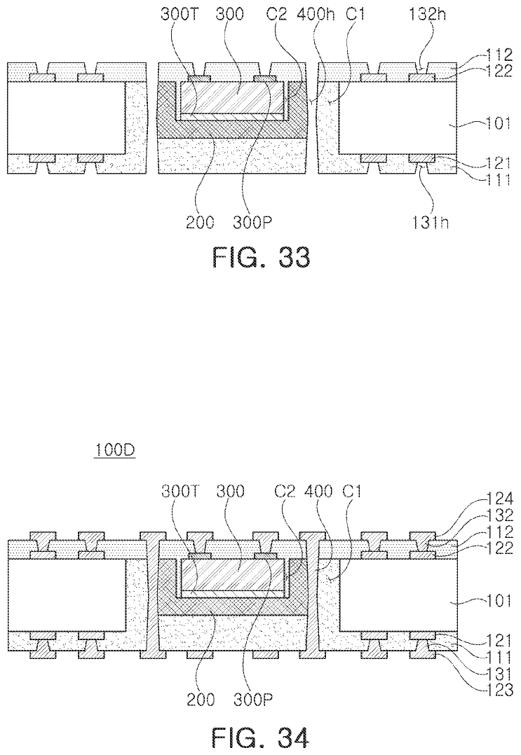

Referring to FIG. 33, a first via hole 131h penetrating through at least a portion of the first encapsulant 111, a second via hole 132h penetrating through at least a portion of the second encapsulant 112, and a heat dissipation via hole 400h penetrating through the first and second encapsulants 111 and 112 and the first cavity C1 may be formed.

The first and second via holes 131h and 132h may be formed using a mechanical processing such as laser processing or a blast method. Accordingly, the first and second via holes 131h and 132h may have a tapered shape in which the cross-sectional area becomes narrower from one side toward the other side. In detail, the first and second via holes 131h and 132h may have a greater end portion far from the core layer 101 than an end portion closer to the core layer 101. Accordingly, the first and second via holes 131h and 132h may have shapes tapered in opposite directions.

The heat dissipation via hole 400h may also be formed using a mechanical processing such as laser processing or a blast method. When processing the heat dissipation via hole 400h, the heat dissipation via hole 400h may be processed to be spaced apart from the heat dissipating member 200, and the heat dissipation via 400 may be formed by plating the inside of the heat dissipation via hole 400h that is disposed to be spaced apart from the heat dissipating member 200 as described above. In this case, a structure of the electronic component-embedded substrate 100C according to the third embodiment in which the heat dissipation via 400 is spaced apart from the heat dissipating member 200 may be derived.

On the other hand, during the processes of manufacturing the electronic component-embedded substrates 100D, 100E and 100E according to the third to fifth embodiments in which the heat dissipation via hole 400h contacts the heat dissipating member 200, the heat dissipation via hole 400h may also be first formed in a position surrounding the vicinity of the heat dissipating member 200 at a location spaced apart from the heat dissipating member 200 by a predetermined distance. Thereafter, the inner wall of the heat dissipation via hole 400h is processed through a desmear process, and as a result, the cross-sectional area of the heat dissipation via hole 400h may be expanded. As the cross-sectional area is expanded by a distance of the heat dissipation via hole 400h spaced from the heat dissipating member 200, the side surface of the heat dissipating member 200 may be exposed to the inner wall of the heat dissipation via hole 400h, and this structure is illustrated in FIG. 33.

As the side surface of the heat dissipation via hole 400h is desmeared, removing impurities from the inner wall of the heat dissipation via hole 400h may be improved, and reliability and uniformity of plating may be secured.

FIG. 34 illustrates a structure in which the first and second vias 131 and 132 and the heat dissipation via 400 are formed by respectively plating-processing the first and second via holes 131h and 132h and the heat dissipation via hole 400h. This is the same as the cross-sectional view of the electronic component-embedded substrate 100D according to the fourth embodiment.

Other contents are substantially the same as described above, and overlapping descriptions will be omitted.

As set forth above, according to an embodiment, an electronic component-embedded substrate in which electronic components are embedded in a cavity, and thus, the thinning thereof may be obtained may be provided.

An electronic component-embedded substrate having improved heat dissipation characteristics by a heat dissipating member being embedded in a cavity may be provided.

An electronic component-embedded substrate having improved heat dissipation characteristics may be provided by embedding an electronic component in a cavity in a heat dissipating member.

An electronic component-embedded substrate in which warpage may be controlled by utilizing a heat dissipating member having a low CTE may be provided.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An electronic component-embedded substrate comprising:
a core layer;
a first cavity disposed in the core layer;
a heat dissipating member disposed in the first cavity and having a second cavity; and
an electronic component disposed in the second cavity,
wherein the heat dissipating member includes a carbon fiber reinforced polymer (CFRP).

2. The electronic component-embedded substrate of claim 1, further comprising a first encapsulant disposed on one surface of the core layer to be disposed in at least a portion of the first cavity, and covering at least a portion of the heat dissipating member.

3. The electronic component-embedded substrate of claim 2, further comprising a heat dissipation via penetrating through at least a portion of the first encapsulant and disposed adjacent to the heat dissipating member.

4. The electronic component-embedded substrate of claim 3, wherein one end of the heat dissipation via is in contact with the heat dissipating member,
wherein a width of the one end of the heat dissipation via is greater than a width of the other end of the heat dissipation via.

5. The electronic component-embedded substrate of claim 3, wherein at least a portion of the heat dissipating member is in contact with an inner wall of the heat dissipation via.

6. The electronic component-embedded substrate of claim 5, wherein the heat dissipation via has a bar-via shape.

7. The electronic component-embedded substrate of claim 2, further comprising a second encapsulant disposed on the other surface of the core layer opposing the one surface thereof,
wherein the second encapsulant is disposed in at least a portion of the second cavity and covers at least a portion of the electronic component.

8. The electronic component-embedded substrate of claim 7, further comprising:
first and second wiring layers disposed on the one surface and the other surface of the core layer, respectively; and
first and second vias penetrating through at least portions of the first and second encapsulants, respectively,
wherein the first and second encapsulants cover at least portions of the first and second wiring layers, respectively.

9. The electronic component-embedded substrate of claim 7, further comprising a through-via penetrating through the core layer and disposed to surround the first cavity,
wherein the through-via connects the first and second wiring layers to each other.

10. The electronic component-embedded substrate of claim 1, further comprising an adhesive film disposed between a lower surface of the second cavity and the electronic component.

11. The electronic component-embedded substrate of claim 1, wherein the second cavity is provided in plural in the heat dissipating member, and
the electronic component is disposed in each of the plurality of second cavities.

12. An electronic component-embedded substrate comprising:
a core layer;
a plurality of first cavities disposed in the core layer;
a first wiring layer disposed on one surface of the core layer;
an electronic component embedded in at least a portion of the plurality of first cavities; and
a heat dissipating member embedded in at least a portion of the plurality of first cavities.

13. The electronic component-embedded substrate of claim 12, wherein in at least a portion of the heat dissipating member, a second cavity is disposed, and
at least a portion of the electronic component is disposed in the second cavity.

14. The electronic component-embedded substrate of claim 12, wherein the heat dissipating member includes a carbon fiber reinforced polymer (CFRP).

15. The electronic component-embedded substrate of claim 12, further comprising a heat dissipation via penetrating through the plurality of first cavities,
wherein at least a portion of a side surface of the heat dissipating member is in contact with an inner wall of the heat dissipation via.

16. The electronic component-embedded substrate of claim 13, further comprising:
a first encapsulant disposed on one surface of the core layer and in at least a portion of the plurality of first cavities; and
a second encapsulant disposed on the other surface of the core layer and in at least a portion of the second cavity.

17. An electronic component-embedded substrate comprising:
a core layer;
a first cavity disposed in the core layer;
a heat dissipating member disposed in the first cavity and having a second cavity;
an electronic component disposed in the second cavity; and
a first heat dissipation via penetrating through the first cavity and being in contact with the heat dissipating member.

18. The electronic component-embedded substrate of claim 17, further comprising a first encapsulant disposed in at least a portion of the first cavity,
wherein the heat dissipating member is disposed in the first encapsulant, and
the first heat dissipation via penetrates through the first encapsulant.

19. The electronic component-embedded substrate of claim 18, further comprising a second heat dissipation via penetrating into the first encapsulant to be in contact with the heat dissipating member,
wherein the second heat dissipation via and the electronic component are disposed on opposing sides of a bottom of the second cavity.

20. The electronic component-embedded substrate of claim 18, further comprising a second encapsulant disposed on in at least a portion of the second cavity.
